(19) United States
(12) Patent Application Publication
(10) Pub. No.: US 2010/0214001 A1
(43) Pub. Date: Aug. 26, 2010

(54) Level Shift Circuit

(75) Inventors: Chow-Peng Lee, Sinshih Township (TW); Aung Aung Yinn, Sinshih Township (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: HIMAX ANALOGIC, INC., Sinshih Township (TW)

(21) Appl. No.: 12/393,472

(22) Filed: Feb. 26, 2009

(51) Int. Cl. H03L 5/00

(52) U.S. Cl. 327/333

(57) ABSTRACT

A level shift circuit includes an inverter, a shifting circuit, a first transistor, and a second transistor. The inverter inverts an original input signal into an inverted input signal. The shifting circuit generates a control signal according to the original input signal, the inverted input signal, and a reference voltage. The first transistor has a gate, a source, and a drain, in which the gate of the first transistor receives the control signal, and the source of the first transistor is connected to a high supply voltage. The second transistor has a gate, a source, and a drain, in which the gate of the second transistor receives the inverted input signal, the drain of the second transistor is connected to the drain of the first transistor, and the source of the second transistor is connected to a ground terminal or a low supply voltage.

### BACKGROUND

1. Field of Invention

The present invention relates to a level shift circuit. More particularly, the present invention relates to a level shift circuit used in a gate pulse modulation circuit.

2. Description of Related Art

A level shift is used for converting a voltage from one level to another level, such as from 5V to 12V, or from 12V to 5V. FIG. 1 shows the circuit diagram of the conventional level shift used in a power control circuit. The level shift 101 for shifting low level (such as 5 v) to high level (such as 12 v) usually includes two PMOS transistors M1, M2 and two NMOS transistors M3, M4, in which the gates of the PMOS M1, M2 are connected to the drains of the NMOS M3, M4, respectively.

If the input IN is 5V and the inverted input INB is 0V, the NMOS M3 receiving the 5V input is turned on, such that the OUTB of the level shifter 101 is 0V. In such situation, the PMOS M2 having gate receiving the 0V is turned on, such that the high supply voltage 12 V can be passed to the output OUT through the PMOS M2, in which the input 5V is shifted to 12 V as a result. The output OUT is inverted through the inverter 103, and is used to drive load (not shown).

In such case, the input signal IN needs to pass through the level shift 101 and the inverter 103 to drive the load, therefore the propagation delay is increased to the delay time of the level shift 101 plus the delay time of the inverter 103. Therefore, there is a need for reducing the propagation delay of the level shift.

### SUMMARY

According to one embodiment of the present invention, a level shift circuit includes an inverter, a shifting circuit, a first transistor, and a second transistor. The inverter inverts an original input signal into an inverted input signal. The shifting circuit generates a control signal according to the original input signal, the inverted input signal, and a reference voltage. The first transistor has a gate, a source, and a drain, in which the gate of the first transistor receives the control signal, and the source of the first transistor is connected to a high supply voltage. The second transistor has a gate, a source, and a drain, in which the gate of the second transistor receives the inverted input signal, the drain of the second transistor is connected to the drain of the first transistor, and the source of the second transistor is connected to a ground terminal or a low supply voltage.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 shows the circuit diagram of the conventional level shift;

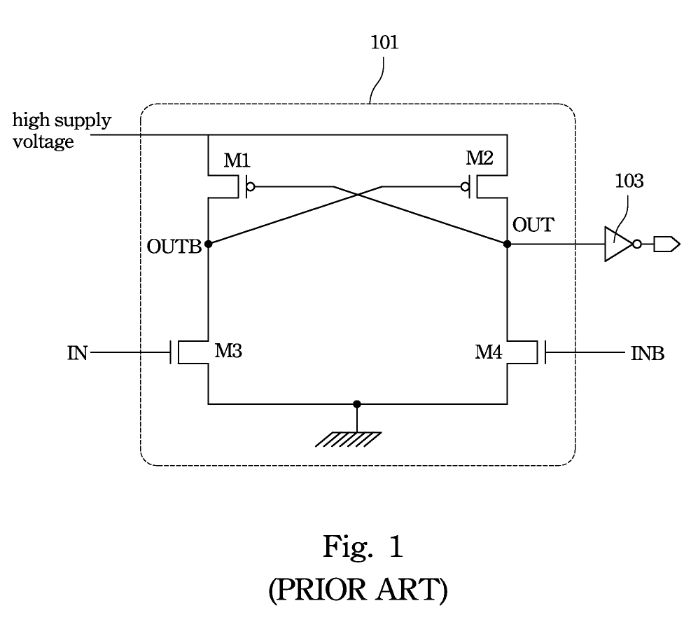

FIG. 2 shows the circuit diagram of the level shift circuit according to one embodiment of the present invention; and

FIG. 3 shows the circuit diagram of the level shift circuit according to another embodiment of the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

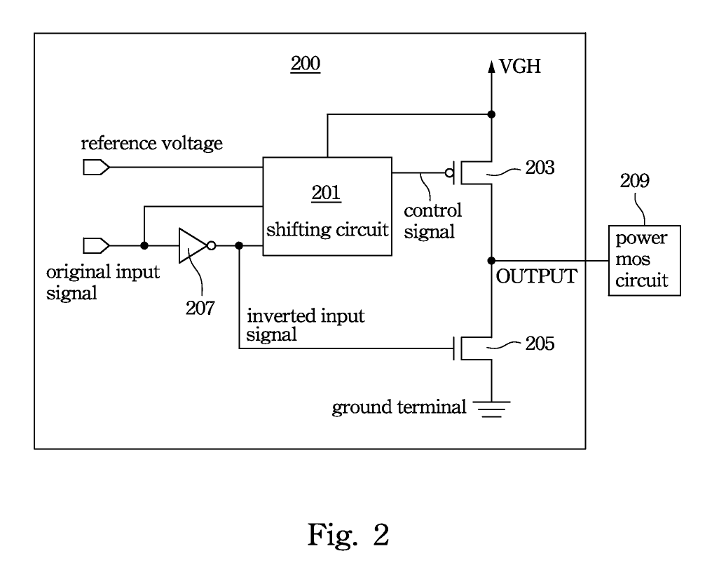

FIG. 2 shows the circuit diagram of the level shift circuit according to one embodiment of the present invention. The level shift circuit 200 includes an inverter 207, a shifting circuit 201, a first transistor, and a second transistor. The inverter 207 inverts an original input signal into an inverted input signal. The shifting circuit 201 generates a control signal according to the original input signal, the inverted input signal, and a reference voltage. The OUTPUT of the level shift circuit 200 drives a power Metal-Oxide-Semiconductor Field-Effect Transistor circuit (power MOS circuit) 209.

The first transistor, such as the P MOSFET (P channel metal oxide semiconductor field effect transistor) first transistor 203, has a gate, a source, and a drain, in which the gate of the first transistor 203 receives the control signal, and the source of the first transistor 203 is connected to a high supply voltage VGH. The second transistor, such as the N MOSFET (N channel metal oxide semiconductor field effect transistor) second transistor 205, has a gate, a source, and a drain, in which the gate of the second transistor 205 receives the inverted input signal, the drain of the second transistor 205 is connected to the drain of the first transistor 203, and the source of the second transistor 205 is connected to a ground terminal or a low supply voltage (not shown). Because the high supply voltage VGH has a voltage range from 0 v to 40 v, and the original input signal has a voltage range from 0 v to 5 v, therefore, the gate-source interface and the drain-source interface of the first transistor 203 needs to endure 40 v; the gate-source interface and the drain-source interface of the second transistor 203 needs to endure 5 v and 40 v respectively.

In the configuration shown in FIG. 2, the inverted input signal is passed to the NMOS second transistor 205 directly (without passing the shifting circuit 201), so the NMOS second transistor 205 can be pulled low by the inverted input signal quickly, such that the OUTPUT can respond to transition of the inverted input signal quickly. Because the inverter 207 has little propagation delay, and the OUTPUT can respond to transition of the inverted input signal quickly, the total propagation delay of the level shift circuit 200 can be reduced.

On the other hand, because the NMOS second transistor 205 is turned off quickly, the OUTPUT can be merely charged by the PMOS first transistor 203, and is free of being discharged by the NMOS second transistor 205, hence the OUTPUT can be pulled high quickly (to the high supply voltage VGH) even if the PMOS first transistor 203 is merely slightly turned on, which further decreases the propagation delay.

In addition, to charge the OUTPUT, the PMOS first transistor 203 needs not to turn on completely, but merely needs to turn on slightly, hence the lowest voltage of the control signal, turning on/off the PMOS first transistor 203, can be shifted to the reference voltage rather than 0 volt, which reduces the voltage swing (up to the high supply voltage VGH, down to the reference voltage) and the transition time of the control signal, and the power consumption of the level shift circuit 200 is also reduced as a result.

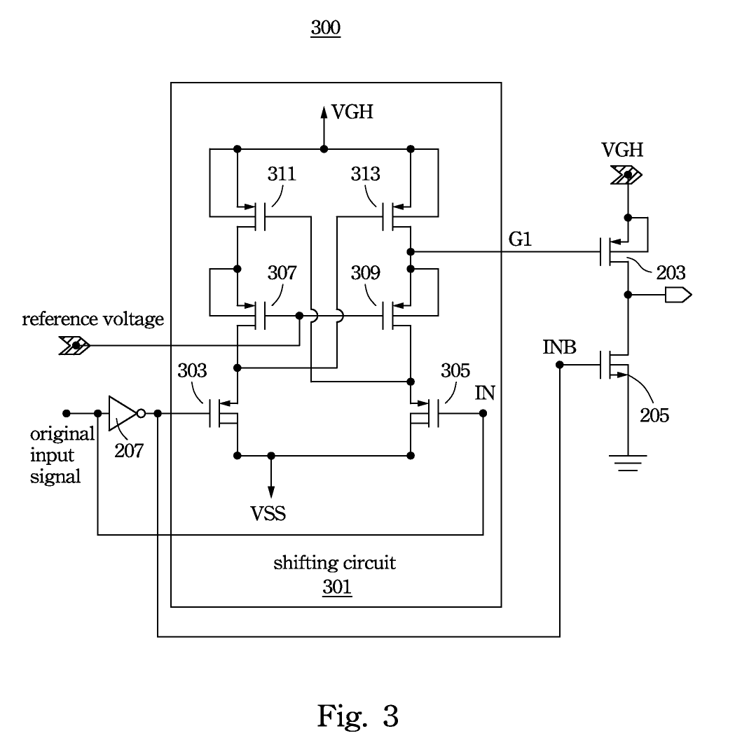

FIG. 3 shows the circuit diagram of the level shift circuit according to another embodiment of the present invention. The level shift circuit 300 includes an inverter 207, a shifting circuit 301, a PMOS first transistor 203, and a NMOS second transistor 205. The inverter 207, the PMOS first transistor 203, and the NMOS second transistor 205 operate similarly to those shown in FIG. 2.

The shifting circuit 301 includes a third transistor 303, a fourth transistor 305, a seventh transistor 307, and an eighth transistor 309. The third transistor 303 has a gate, a drain, and a source, in which the gate of the third transistor 303 is connected to the inverter 207 for receiving the inverted input signal, the drain of the third transistor 303 is connected to a low supply voltage VSS. The fourth transistor 305 has a gate, a drain, and a source, in which the gate of the fourth transistor 305 receives the original input signal, the drain of the fourth transistor 305 is connected to the low supply voltage VSS.

The fifth transistor 307 includes a gate, a drain, and a source, in which the gate of the fifth transistor 307 receives the reference voltage, the drain of the fifth transistor 307 is connected to the source of the third transistor 303. The sixth transistor 309 has a gate, a drain, and a source, in which the gate of the sixth transistor 309 receives the reference voltage, the drain of the sixth transistor 309 is connected to the source of the fourth transistor 305. The third transistor 303, the fourth transistor 305, the fifth transistor 307, and the sixth transistor 309 are P channel MOSFET (P channel metal oxide semiconductor field effect transistors).

The level shift circuit further includes a seventh transistor 311 and an eighth transistor 313. The seventh transistor 311 has a gate, a drain, and a source, in which the gate of the seventh transistor 311 is connected to the source of the fourth transistor 305, the drain of the seventh transistor 311 is connected to the source of the fifth transistor 307, and the source of the seventh transistor 311 receives the high supply voltage VGH. The eighth transistor 313 has a gate, a drain, and a source, in which the gate of the eighth transistor 313 is connected to the source of the third transistor 303, the drain of the eighth transistor 313 is connected to the source of the sixth transistor 309, and the source of the eighth transistor 313 receives the high supply voltage VGH.

The gate of the first transistor 203 is connected to the source of the sixth transistor 309. With such configuration, the minimal voltage value on the gate G1 of the first transistor 203 is the reference voltage plus the threshold voltage of the sixth transistor 309, and the maximum voltage value on the gate of the first transistor 203 is the voltage value of the high supply voltage VGH. That is, the control signal is shifted by the threshold voltage of sixth transistor 309 from the reference voltage, and the voltage on the gate of the first transistor 203 swings between the reference voltage and the high supply voltage VGH.

If the high supply voltage VGH is approximately 40 Volt, the reference voltage is about 5 volt, and the threshold voltage of the sixth transistor 309 is about 0.7 v, then the voltage on the gate of the first transistor 203 swings from 5.7 v (reference voltage plus the threshold) to 40 v (VGH), rather from 0V to 40V. In other words, the voltage swing on the gate of the first transistor 203 is reduced, therefore, the power consumption and the transition time of the control signal received by the first transistor 203 is decreased, hence the propagation delay of the level shift circuit 300 is decreased.

According to one of the above embodiments, the NMOS transistor of the level shift circuit can be pulled low quickly, such that the OUTPUT of the level shift circuit can respond to change of the input signal quickly, the propagation delay of the level shift circuit can be reduced. According to one of the above embodiments, the OUTPUT of the level shift circuit can be charged by the PMOS transistor and is free of being discharged by the NMOS transistor, hence the OUTPUT can be pulled high quickly, which also decreases the propagation delay.

In addition, according to another one of the above embodiments, the lowest voltage of the control signal can be shifted to the reference voltage rather than 0 volt, which reduces the voltage swing and the transition time of the control signal, and the power consumption of the level shift circuit is reduced as a result.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A level shift circuit, comprising:
an inverter inverting an original input signal into an inverted input signal;
a shifting circuit generating a control signal according to the original input signal, the inverted input signal, and a reference voltage, wherein the shifting circuit comprises:
a third transistor having a gate, a drain, and a source, wherein the gate of the third transistor is connected to the inverter for receiving the inverted input signal, the drain of the third transistor is connected to a low supply voltage;
a fourth transistor having a gate, a drain, and a source, wherein the gate of the fourth transistor receiving the input signal, the drain of the fourth transistor is connected to the low supply voltage;
a fifth transistor having a gate, a drain, and a source, wherein the gate of the fifth transistor receiving the reference voltage, the drain of the fifth transistor is connected to the source of the third transistor;
a sixth transistor having a gate, a drain, and a source, wherein the gate of the sixth transistor receiving the reference voltage, the drain of the sixth transistor is connected to the source of the fourth transistor;
a seventh transistor having a gate, a drain, and a source, wherein the gate of the seventh transistor is directly connected to the source of the fourth transistor, the drain of the seventh transistor is connected to the source of the fifth transistor, and the source of the seventh transistor receives the high supply voltage; and
an eighth transistor having a gate, a drain, and a source, wherein the gate of the eighth transistor is directly connected to the source of the third transistor, the drain of the eighth transistor is connected to the source of the sixth transistor, and the source of the eighth transistor receives the high supply voltage;
a first transistor having a gate, a source, and a drain, wherein the gate of the first transistor receiving the control signal, and the source of the first transistor is connected to a high supply voltage; and
a second transistor having a gate, a source, and a drain, wherein the gate of the second transistor receives the inverted input signal, the drain of the second transistor is connected to the drain of the first transistor, and the source of the second transistor is connected to a ground terminal or a low supply voltage.

2. The level shift circuit as claimed in claim 1, wherein the first transistor is a P channel field effect transistor.

3. The level shift circuit as claimed in claim 1, wherein the second transistor is an N channel field effect transistor.

4. The level shift circuit as claimed in claim 1, wherein the control signal is generated by shifting the reference voltage with a threshold voltage.

5. (canceled)

6. The level shift circuit as claimed in claim 1, wherein the third transistor, the fourth transistor, the fifth transistor, and the sixth transistor are P channel field effect transistors.

7. (canceled)

8. The level shift circuit as claimed in claim 1, wherein the gate of the first transistor is connected to the source of the sixth transistor, and the voltage on the gate of the first transistor swings between the reference voltage and the high supply voltage.

9. The level shift circuit as claimed in claim 1, wherein the minimal voltage value on the gate of the first transistor is the reference voltage plus the threshold voltage of the sixth transistor, and the maximum voltage value on the gate of the first transistor is the voltage value of the high supply voltage.

10. The level shift circuit as claimed in claim 1, wherein the high supply voltage is approximately 40 Volt.

11. The level shift circuit as claimed in claim 1, wherein the input signal swings between approximately 0 volt and approximately 5 volt.

12. The level shift circuit as claimed in claim 1, further comprising a power Metal-Oxide-Semiconductor Field-Effect Transistor (MOSFET) circuit connected to the drain of the first transistor.
